(19) United States
(12) Patent Application Publication
(10) Pub. No.: US 2005/0016836 A1
(43) Pub. Date: Jan. 27, 2005

(54) Single layer CoTbAg thin films for heat assisted magnetic recording

(76) Inventors: Po-Cheng Kuo, Taipei (TW); Chun-Yuan Chou, Taipei (TW); Chao-Te Lee, Taipei (TW); Chu-Long Shen, Taipei (TW); Ching-Ray Chang, Taipei (TW)

Correspondence Address: ANTHONY R BARKUME, 20 GATEWAY LANE, MANORVILLE, NY, 11949, US

(21) Appl. No.: 10/891,763

(22) Filed: Jul. 14, 2004

(30) Foreign Application Priority Data
Jul. 14, 2003 (TW) 092119186

(51) Int. Cl. C23C 14/32

(52) U.S. Cl. 204/192.15; 204/192.2

(57) ABSTRACT

The present invention includes that using single layer amorphous CoTbAg thin films as heat assisted magnetic recording (HAMR) media, and the method for producing these CoTbAg amorphous thin films. Co_{69.48-X}Tb_{30.52}Ag_{X} films with x=0˜25.68 at. % are fabricated by DC or RF magnetron sputtering and rotating substrate. Two kinds of targets can be used. One is the CoTbAg alloy target. The other one consists of Co, Tb and Ag three targets. The CoTbAg film is prepared by co-sputtering of Co, Tb and Ag targets. The film composition can be controlled by changing the sputtering power density of each target. CoTbAg films are deposited on glass substrate or nature-oxide silicon wafer at room temperature. These films have high saturation magnetization and high perpendicular coercivity. They have amorphous structure and can be applied to HAMR media.

### FIELD OF THE INVENTION

The present invention is related to the method for producing single layer amorphous CoTbAg thin films with high saturation magnetization and high perpendicular coercivity that can be used in the heat assisted magnetic recording (HAMR) media.

### BACKGROUND OF THE INVENTION

The heat assisted magnetic recording (HAMR) method with perpendicular thermo-magnetic writing and magnetic flux reading is recently proposed to increase the recording density of the magnetic disk (J. J. M. Ruigrok, R. Coehoorn, S. R. Cumpson, and H. W. Kesteren, “Disk recording beyond 100 Gb/in.²: Hybrid recording?”, J. Appl. Phys. Vol.87, no.9, pp.5398-5403, 2000; H. Saga, H. Nemoto, H. Sukeda, and M. Takahashi, “New Recording Method Combining Thermo-Magnetic Writing and Flux Detection”, Jpn. J. Appl. Phys., Part 1 Vol.38, pp.1839-1840, 1999). This method enables perpendicular magnetic domains to be formed in an amorphous film medium and utilizes a high-sensitivity magnetic flux detector [for example, a giant magnetoresistive (GMR) head or a tunneling magnetoresistive (TMR) head]. The recording media for HAMR must satisfy three requirements: (1) they must provide satisfactory magneto-optical writing performance; (2) they must have a large saturation magnetization, Ms, that generates sufficient magnetic flux for the GMR head or the TMR head readout, and (3) they must have a large perpendicular coercivity, Hc, to resist self-demagnetization. The traditional magneto-optical (MO) recording medium can not be used as HAMR media. Because, the saturation magnetization Ms value of the MO medium at room temperature is too small to generate sufficient magnetic flux for GMR or TMR head readout. The bilayer structure, including a readout layer and a recording layer, had been proposed to solve this problem (H. Nemoto, H. Saga, H. Sukeda, and M. Takahashi, “Exchange-Coupled Magnetic Bilayer Media for Thermomagnetic Writing and Flux Detection”, Jpn. J. Appl. Phys., Part 1 Vol.38, pp.1841-1842, 1999). Their recording layer has good thermomagnetic writing characteristics and a high perpendicular coercivity Hc at room temperature. And the readout layer has a large saturation magnetization Ms at room temperature, thus generates sufficient flux density for GMR or TMR head sensing.

The present invention replaces the currently used doubly layered medium by a single layer CoTbAg recording medium and presents the method for producing single layer amorphous CoTbAg thin films with high saturation magnetization and high perpendicular coercivity.

### SUMMARY OF THE INVENTION

The objective of present invention is to fabricate a single layer amorphous CoTbAg thin film with high saturation magnetization and high perpendicular coercivity, that can be used in the heat assisted magnetic recording (HAMR) media.

According to the present invention, a method for producing the high saturation magnetization and high perpendicular coercivity of CoTbAg amorphous films comprises steps of:
provide a substrate and a CoTbAg target;
put the substrate and the CoTbAg target in a magnetron sputtering system; and
have the magnetron sputtering system to form a CoTbAg amorphous film on the substrage according to the CoTbAg target.

In accordance with one aspect of the present invention, a power supply for the magnetron sputtering system is selected from a group consisting of DC or RF.

In accordance with one aspect of the present invention, the CoTbAg target is selected from a group consisting of an CoTbAg alloy target or Co, Tb and Ag three targets.

In accordance with one aspect of the present invention, the high saturation magnetization and high perpendicular coercivity of CoTbAg amorphous film is sputtered onto the substrate; and the substrate is a glass substrate or a natural oxidized Si wafer.

In accordance with one aspect of the present invention, a sputtering argon pressure of the magnetron sputtering system is in the range between 2 and 12 mTorr.

In accordance with one aspect of the present invention, the sputtering argon pressure is 8 mTorr for optimization.

In accordance with one aspect of the present invention, a DC power for the magnetron sputtering system is in the range of 1 and 5 W/cm².

In accordance with one aspect of the present invention, the DC power is 3 W/cm² for optimization.

In accordance with one aspect of the present invention, a RF power of the magnetron sputtering system is in the range of 3 and 7 W/cm².

In accordance with one aspect of the present invention, the RF power is 5 W/cm² for optimization.

In accordance with one aspect of the present invention, a temperature of the substrate is less than 50° C.

In accordance with one aspect of the present invention, the best temperature of the substrate is about 25° C.

In accordance with one aspect of the present invention, an atomic ratio of Co:Tb:Ag in the film is in the range of 68.15:30.52:1.33 to 43.8:30.52:25.68.

In accordance with one aspect of the present invention, the atomic ratio of Co:Tb:Ag in the film is about 67.23:30.52:2.25 for optimization.

### BRIEF DESCRIPTION OF THE DRAWINGS

The present invention will be described in detail with reference to the accompany drawings, in which:

FIGS. 1.(a) and 1.(b) are the TEM bright field images and electron diffraction pattern of the amorphous Co_{36.48}Tb_{30.52}Ag₃₃ alloy film, respectively;

FIG. 2.(a) shows variations of saturation magnetization (Ms) and perpendicular remanence (Mr) with Ag content of the Co_{69.48-X}Tb_{30.52}Ag_{X} film, and (b) shows relationship between perpendicular coercivity (Hc) and Ag content of the Co_{69.48-X}Tb_{30.52}Ag_{X} film;

FIG. 3. is the M-H loop of the Co_{67.23}Tb_{30.52}Ag_{2.25} amorphous film; and

FIG. 4. shows relations among Ms, Hc and temperature of the Co_{67.23}Tb_{30.52}Ag_{2.25} film.

### DETAILED DESCRIPTION OF THE PREFERRED EMBODIMENT

Co_{69.48-X}Tb_{30.52}Ag_{X} films with x=0˜25.68 at % are fabricated on glass and natural oxidized Si(100) substrates by magnetron sputtering at room temperature. The target is a Co disk overlaid with Tb and Ag pieces, to yield the desired film composition, or a CoTbAg alloy target. The substrate is rotated in order to obtain a uniform composition of the film. The CoTbAg magnetic film is sandwiched between SiN_{X} protective layers to prevent oxidation. The SiN_{X} protective layer is prepared by RF magnetron sputtering of the Si₃N₄ target. The thickness of the magnetic layer and the protective layer is 75 nm and 30 nm, respectively.

Table 1 lists the sputtering parameters for the preparation of Co_{69.48-X}Tb_{30.52}Ag_{X} thin films. Base pressure of the sputter chamber is approximately 2×10⁻⁷ Torr and films are deposited under an argon pressure P_{Ar} between 2 and 12 mTorr in order to get higher magnetic properties. P_{Ar}=8 mTorr is preferred for optimization.

TABLE 1

| Substrate temperature (Ts) | Ambient temperature | |
|---|---|---|
| RF power density | 3˜7 W/cm² for CoTbAg target | |
| DC power density | 1˜5 W/cm² for CoTbAg target | |
| Base vacuum | 2 × 10⁻⁷ | Torr |
| Distance between substrate | 6 | cm |
| and target | | |
| Argon pressure | 2˜12 | mTorr |
| Argon flow rate | 24 | ml/min |

The structure of the film is examined by transmission electron microscope (TEM). The composition of the film is determined by energy disperse spectroscopy (EDS). The film thickness is measured by atomic force microscopy (AFM) and α-step. The magnetic properties of the films are measured by a vibrating sample magnetometer (VSM) with a maximum applied field of 13 kOe.

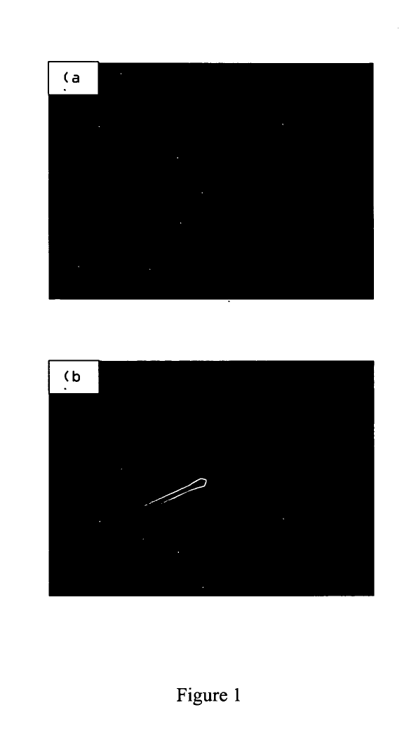

FIG. 1(a) and (b) show the TEM bright field images and electron diffraction pattern of the amorphous Co_{36.48}Tb_{30.52}Ag₃₃ alloy film, respectively. No crystal grains can be seen in the film and the shape of the electron diffraction pattern is a broad halo, implying that the film is amorphous.

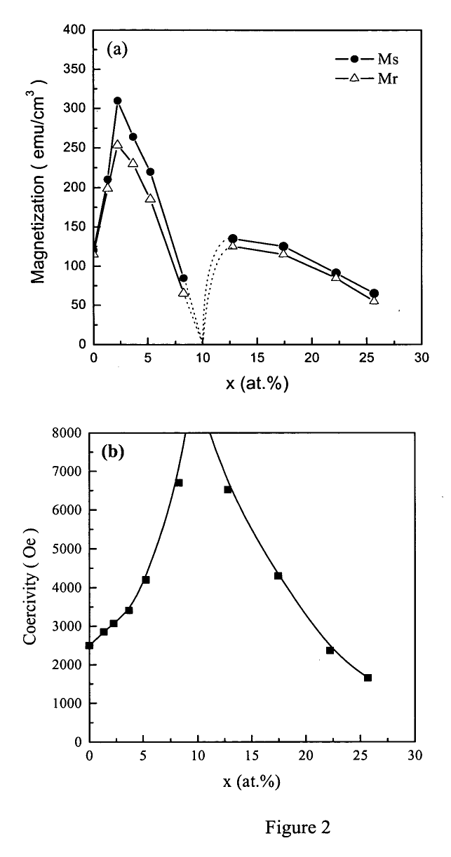

FIG. 2(a) shows the variations of Ms and Mr with Ag content of the Co_{69.48-X}Tb_{30.52}Ag_{X} film, and FIG. 2(b) is the relationship between Hc and Ag content of the Co_{69.48-X}Tb_{30.52}Ag_{X} film. It reveals that the Ms and Mr values of the Co_{69.48}Tb_{30.52} film (x=0 at. %) are about 125 emu/cm³ and 115 emu/cm³, respectively. Ms and Mr increase rapidly with Ag content as x<2.25 at. % and then decrease rapidly with increasing Ag content as x>2.25 at. %. The maximum Ms and Mr values occur at x˜2.25 at. %: they are about 310 emu/cm³ and 255 emu/cm³, respectively.

The Hc value increases from about 2500 Oe to 7200 Oe as Ag content increases from 0 at. % to 8.26 at. %, and Hc decreases rapidly with increasing Ag content when x>10 at. %. The variation of Ms and Hc values with Ag content depends not only the spin polarization of Ag atoms but also the shift of compensation temperature T_{comp}.

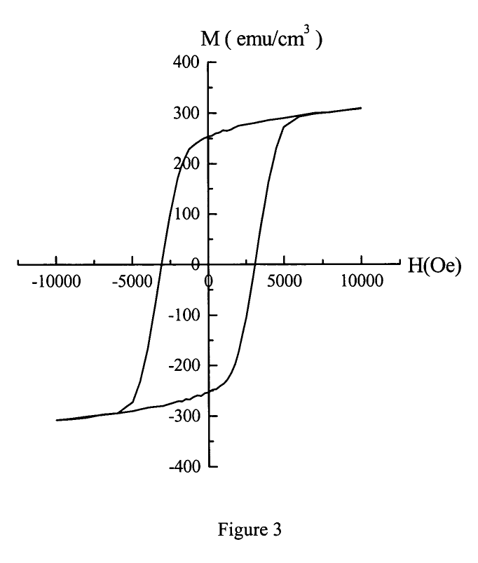

FIG. 3 is the M-H loop of the Co_{67.23}Tb_{30.52}Ag_{2.25} film at room temperature, where the applied filed is perpendicular to the film plane. The saturation magnetization of this film is about 310 emu/cm³; Mr is about 255 emu/cm³, and the perpendicular coercivity is about 3100 Oe.

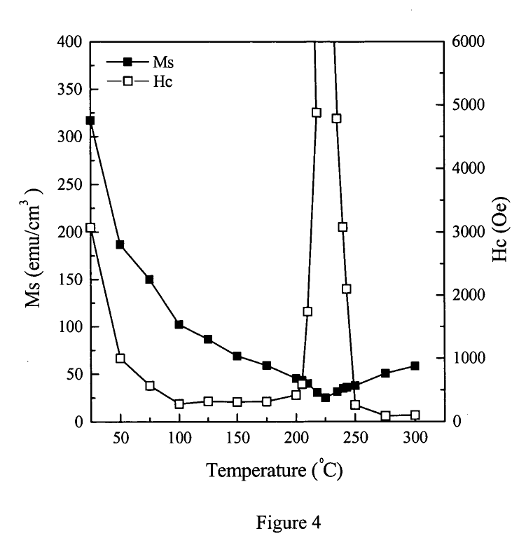

FIG. 4. shows the relationships among Ms, Hc and temperature of this film, the substrate is silicon wafer. Ms of the film decreases from 310 emu/cm³ to about 25 emu/cm³ as the temperature increases from 25° C. to 225° C. Its Hc decreases from 3100 Oe to about 300 Oe as the temperature increases from 25° C. to 100° C., then remains at this low Hc as temperature is further increased to 200° C. Hc increases rapidly with temperature from 200° C. to 225° C. and Hc decreases rapidly to about 250 Oe as temperature increases from 225° C. to 250° C.

While the invention has been described in terms of what are presently considered to be the most practical and preferred embodiments, it is to be understood that the invention need not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. A method for producing the high saturation magnetization and high perpendicular coercivity of CoTbAg amorphous films comprising steps of:
providing a substrate and a CoTbAg target;
putting said substrate and said CoTbAg target in a magnetron sputtering system; and
having said magnetron sputtering system to form a CoTbAg amorphous film on said substrage according to said CoTbAg target.

2. The method according to claim 1, wherein a power supply for said magnetron sputtering system is selected from a group consisting of DC or RF.

3. The method according to claim 1, wherein said CoTbAg target is selected from a group consisting of an CoTbAg alloy target or Co, Tb and Ag three targets.

4. The method according to claim 1, wherein the high saturation magnetization and high perpendicular coercivity of CoTbAg amorphous film is sputtered onto said substrate; and said substrate is a glass substrate or a natural oxidized Si wafer.

5. The method according to claim 1, wherein a sputtering argon pressure of said magnetron sputtering system is in the range between 2 and 12 mTorr.

6. The method according to claim 5, wherein said sputtering argon pressure is 8 mTorr for optimization.

7. The method according to claim 1, wherein a DC power for said magnetron sputtering system is in the range of 1 and 5 W/cm².

8. The method according to claim 7, wherein said DC power is 3 W/cm² for optimization.

9. The method according to claim 1, wherein a RF power of said magnetron sputtering system is in the range of 3 and 7 W/cm².

10. The method according to claim 9, wherein said RF power is 5 W/cm² for optimization.

11. The method according to claim 1, wherein a temperature of said substrate is less than 50° C.

12. The method according to claim 11, wherein the best temperature of said substrate is about 25° C.

13. The method according claim 1, wherein an atomic ratio of Co:Tb:Ag in said film is in the range of 68.15:30.52:1.33 to 43.8:30.52:25.68.

14. The method according to claim 13, wherein said atomic ratio of Co:Tb:Ag in the film is about 67.23:30.52:2.25 for optimization.
